(19) United States
(12) Patent Application Publication
(10) Pub. No.: US 2025/0315167 A1
(43) Pub. Date: Oct. 9, 2025

(54) INDEPENDENT FLASH TRANSLATION LAYER STORAGE FOR A MEMORY SYSTEM

(71) Applicant: Micron Technology, Inc., Boise, ID (US)

(72) Inventors: Marco Redaelli, München (DE); Gaurav Sinha, Unterschleißheim (DE)

(21) Appl. No.: 19/090,283

(22) Filed: Mar. 25, 2025

Related U.S. Application Data
(60) Provisional application No. 63/574,137, filed on Apr. 3, 2024.

(51) Int. Cl. G06F 3/06

(52) U.S. Cl. CPC G06F 3/0619; G06F 3/0659; G06F 3/0679

(57) ABSTRACT

Methods, systems, and devices for independent flash translation layer (FTL) storage for a memory system are described. A memory system may be configured with multiple independent FTLs each defined by a respective set of instructions stored as metadata in a respective storage region of a memory device. The memory system may perform one or more FTL functions of an independent FTL on data stored in the respective storage region based on the metadata. Each port of the memory system may be mapped to an FTL and a storage region, where a port may couple the memory system with one or more external systems. In response to detecting a corrupted FTL, the storage region associated with the corrupted FTL may enter a first operational mode associated with reduced write capabilities while other storage regions of the memory system may remain in a second operational mode.

### CROSS REFERENCE

The present application for patent claims priority to U.S. Patent Application No. 63/574,137 by Redaelli et al., entitled “INDEPENDENT FLASH TRANSLATION LAYER STORAGE FOR A MEMORY SYSTEM,” filed Apr. 3, 2024, which is assigned to the assignee hereof, and which is expressly incorporated by reference in its entirety herein.

### TECHNICAL FIELD

The following relates to one or more systems for memory, including independent flash translation layer storage for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports independent flash translation layer (FTL) storage for a memory system in accordance with examples as disclosed herein.

FIG. 2 shows an example of a system that supports independent FTL storage for a memory system in accordance with examples as disclosed herein.

FIG. 3 shows an example of a process flow that supports independent FTL storage for a memory system in accordance with examples as disclosed herein.

FIG. 4 shows a block diagram of a memory system that supports independent FTL storage for a memory system in accordance with examples as disclosed herein.

FIG. 5 shows a flowchart illustrating a method or methods that support independent FTL storage for a memory system in accordance with examples as disclosed herein.

### DETAILED DESCRIPTION

Some memory systems may utilize a flash translation layer (FTL) (e.g., a set or library of functions) to perform one or more operations associated with data management in one or more memory devices of the memory system. In some cases, the FTL may include firmware functions that are executed by a controller based on instructions or parameters stored as metadata in the one or more memory devices, and the FTL, the metadata, or both, may experience corruption (e.g., may become corrupted, may include corrupted data). In response to detecting the corruption, and to prevent further corruption, the memory system may modify the FTL, the metadata, or both, such that the one or more memory devices may enter into an operational mode associated with reduced write performance. A controller of the memory system may use the FTL to manage data associated with multiple different external systems that are supported by the memory system, such as in a central computing context. If the FTL is corrupted and the memory system modifies the FTL or the metadata as described, the one or more memory devices may enter the operational mode (e.g., a safe mode) associated with decreased write performance and some operations for the multiple different external systems may be paused or otherwise affected until the memory system is repaired. Such operations may increase latency and reduce functional capability at the memory device.

According to techniques described herein, a memory system may be configured with multiple independent FTLs (e.g., four, or some other quantity of FTLs). Each FTL may be associated with (e.g., may execute based on) a respective set of instructions or parameters stored as metadata in a respective storage region in a memory device. That is, one or more memory devices of a memory system may be divided into a plurality of storage regions, and each storage region may be mapped to a respective FTL. In some cases, each storage region may include an independent set of the metadata for performing one or more FTL functions of an independent FTL on data stored in a corresponding storage region. The memory system may include ports configured to couple the memory system with the external systems, and each port of the memory system may be mapped to a corresponding FTL and a respective storage region. A port may couple the memory system with one or more external systems, and data associated with the one or more external systems may be stored in the storage region corresponding to the port.

In some cases, the memory system may detect corruption associated with an independent FTL (e.g., with the metadata associated with an independent FTL). For example, the corruption may be within the metadata associated with the independent FTL. In response to detecting the corruption associated within the FTL, the storage region associated with the corrupted FTL may enter the operational mode associated with decreased write performance (e.g., a first operational mode, as used herein), while another storage region (e.g., corresponding to other independent FTLs) may remain in a second operational mode associated with higher performance. For example, a storage region may enter the first operational mode via the memory system modifying the metadata associated with the storage region, which may reduce a write capability of the storage region. The separation of the FTLs may thereby permit continued performance for one or more external systems regardless of a failure associated with a single FTL, which may reduce latency and improve system performance and reliability, among other examples. Thus, using multiple FTLs may reduce the likelihood that corruption (or failure) of one system will adversely affect other systems associated with the memory system.

In addition to applicability in memory systems as described herein, techniques for independent FTL storage for memory systems may be generally implemented to improve the performance of various electronic devices and systems (including artificial intelligence (AI) applications, augmented reality (AR) applications, virtual reality (VR) applications, gaming, and automotive computing or memory management). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by allowing a memory system to operate at a higher functionality even when a portion of the data (e.g., one of the multiple FTLs) becomes corrupted, which may increase the performance capabilities and reliability of the memory system in the event of a corrupted FTL, among other benefits.

Features of the disclosure are illustrated and described in the context of systems, devices, and circuits. Features of the disclosure are further illustrated and described in the context of a memory system, a process flow, and flowcharts.

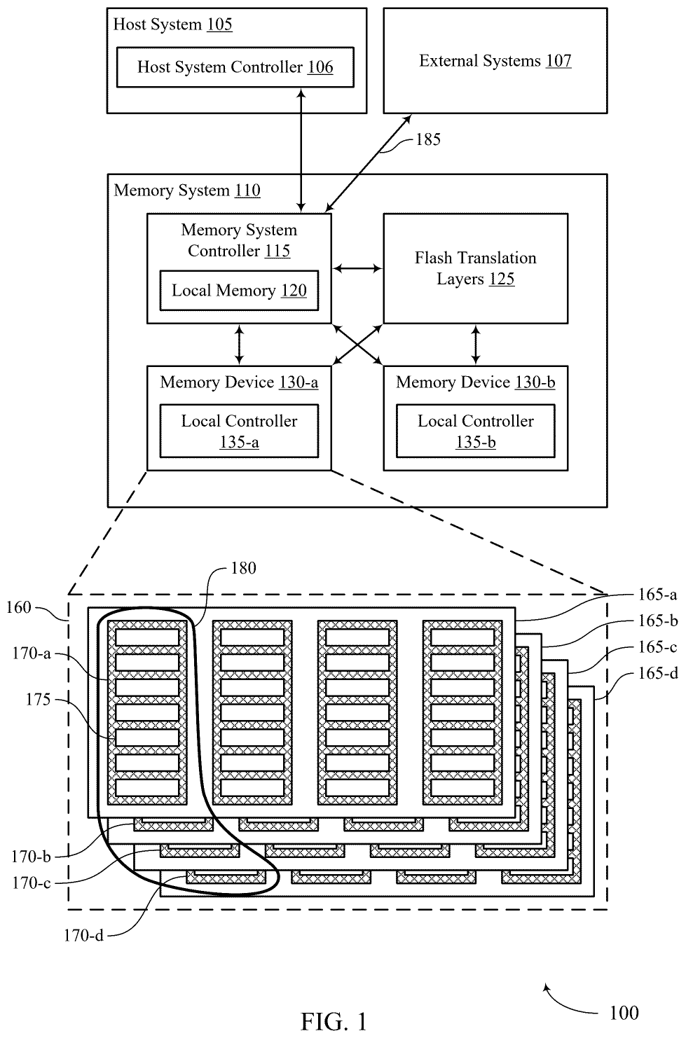

FIG. 1 shows an example of a system 100 that supports independent FTL storage for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained, and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms, FTL functions) for a memory device 130 using an FTL of the FTLs 125, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105). One or more aspects of “garbage collection” (e.g., and other operations) may be included in a set of FTL functions performed by the FTLs 125.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that supports independent FTL storage for a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, one or more external systems 107 (e.g., one or more external devices) may communicate with the memory system 110. For example, the external systems 107 may transmit signaling to the memory system controller 115, where the signaling may indicate data, commands, or both, to the memory system controller 115. In some cases, the external systems 107 may be other host systems, systems on chips (SOCs), sensors, external devices, or any combination thereof. For example, an SOC may be a type of integrated circuit (IC) design that combines one or more high-level function elements (e.g., sensors, memory arrays, computational elements) onto a single chip. In some examples, the external systems 107 may be SOCs in an automotive application, and may transmit signaling indicating data to the memory system controller 115. In some cases, the data may be associated with measurements made by the external systems 107. The memory system controller 115 may store the data from the external systems 107 in one or more storage regions in the memory devices 130, and may also store metadata in one or more storage regions in the memory devices 130. According to techniques described herein, the memory system controller 115 may perform FTL functions on the data using the FTLs 125 and the metadata.

In some cases, the techniques described herein may apply to an automotive electronic system. For example, some automotive vehicles may be equipped with a quantity (e.g., dozens) of electronic control units (ECUs) (e.g., such as the memory system controller 115), where each ECU may be responsible for a different function. As automotive vehicles become more connected and autonomous (e.g., including more external systems 107, becoming more complex), a central computer may improve performance and reduce latency as compared to multiple ECUs. Additionally, consolidating the ECUs into a single central computer may reduce weight and space used by the multiple ECUs. In some cases, central computing may be a computing architecture where a central computer (e.g., central server) performs most or all of the computing. For example, central computing may provide for a single device (e.g., memory system, computer) to handle the processing, data storage, and requests for a system.

Utilizing centralized computing (e.g., a centralized system) may be associated with one or more other benefits. As described herein, the benefits may include improved performance and efficiency as compared to multiple ECUs. For example, a central computer may streamline data processing and communication. Additionally, or alternatively, the benefits may include reduced complexity of the automotive electronic system. For example, a central computer may consolidate multiple ECUs into a single unit, increasing ease of management and maintenance of the systems. The benefits may also include increased safety of the automotive vehicle. For example, a central computer may provide fewer points of failure for critical systems as compared to multiple ECUs, preventing accidents caused by failures in individual ECUs. In some aspects, the techniques described herein may improve safety in an automotive scenario by reducing the scenarios in which failure (e.g., non-volatile memory failure) may occur (e.g., specifically in multiport non-volatile memory devices) and impair the functions of a memory system in the automotive scenario.

The techniques described herein may be associated with FTLs (e.g., FTLs 125), which may include a controller or a firmware capable of performing garbage collection, wear leveling, L2P mapping, and other operations, within a flash memory system. In some cases, flash memory may not support overwriting in place (e.g., writing to a memory location that is storing data). Accordingly, memory devices with flash memory (e.g., flash devices) may utilize a translation layer to map logical blocks of the memory device to their locations within physical memory of the memory device (e.g., physical flash memory). Such a translation layer may be referred to as an FTL. In some cases, an FTL may obscure (e.g., hide) the complexity of managing memory in a flash device by providing a logical block interface for the flash device. For example, because the flash device may not support overwriting memory (e.g., flash pages) in place, the FTL may map logical blocks to physical blocks and erase blocks. In some cases, an FTL may be of one or more generic classes, including FTLs for mapping pages of memory to logical blocks, and FTLs for managing wear in a memory system. Additionally, or alternatively, an FTL may be of more than one of the generic classes, and may perform more than one function.

Some memory systems (e.g., memory systems with non-volatile memory devices) may utilize an FTL (e.g., a library of functions) to perform one or more operations associated with data management in one or more memory devices of the memory system. For example, the one or more operations may include garbage collection operations, L2P table updating operations, bad block management operations, cache management operations, wear leveling operations, or any combination thereof. In some cases, an FTL may include firmware functions that are executed by a controller (e.g., such as the memory system controller 115) based on instructions or parameters stored as metadata in the memory device (e.g., such as memory devices 130). In some cases, the FTL, the metadata, or both, may experience corruption (e.g., may become corrupted, may include corrupted data). In response to detecting the corruption, and to prevent further corruption, a memory device associated with the corrupted FTL may enter into an operational mode associated with reduced performance (e.g., an emergency mode, a write protected mode, a read only mode, a first operational mode as used herein). For example, the memory device may enter the first operational mode based on the memory system modifying the metadata such that the memory device performs a limited set of functions (e.g., reducing write capabilities)

In some cases, a controller of the memory system (e.g., memory system controller 115) may use the FTL to manage data associated with multiple different external systems (e.g., SOCs, external devices, sensors, the external systems 107) that are supported by (e.g., execute on) the memory system, such as in a central computing context (e.g., in an automotive memory application, among other examples). If the FTL is corrupted and the memory device enters the operational mode associated with decreased performance, operations (e.g., write operations) for the multiple different external systems may be paused at the memory system until the memory system is repaired (e.g., the corruption in the FTL or metadata is removed or replaced). Such operations may increase latency and reduce functional capability at the memory system.

According to techniques described herein, the memory system 110 may include multiple independent FTLs (e.g., up to four), such as the FTLs 125. Each FTL of the FTLs 125 may be defined by a respective set of instructions or parameters stored as metadata in a respective storage region in one or more memory devices 130. That is, a memory device 130 of the memory system 110 may be divided into a plurality of storage regions (e.g., sets of memory cells), and each storage region may be mapped to an independent FTL of the FTLs 125. In some cases, each storage region may include the metadata (e.g., an independent set of metadata values) associated with one or more FTL functions of an independent FTL on data stored in the respective storage region. The memory system 110 may be coupled with (e.g., may include) one or more ports 185, where each port of the one or more ports 185 may be mapped to a corresponding FTL of the FTLs 125 and a respective storage region. Additionally, or alternatively, each port of the one or more ports 185 may include one or more lanes, where each lane in the port 185 may couple the memory system 110 (e.g., the memory system controller 115) with a respective external memory system of the external systems 107.

In some cases, the memory system 110 may detect corruption associated with an FTL of the FTLs 125. For example, the memory system controller 115 or another structure in the memory system 110 may detect corrupted metadata associated with the FTL. In response to detecting the corruption associated with the FTL, the storage region associated with the corrupted FTL may enter the first operational mode associated with decreased write performance (e.g., the memory system controller 115 may modify the metadata stored in the storage region to set the storage region to the first operational mode), while the other storage region (e.g., corresponding to the other FTLs of the FTLs 125) may remain in a second operational mode (e.g., a normal mode, a write capable mode). The independence of the FTLs 125 may thereby permit continued performance and execution the external systems 107 regardless of a failure in one FTL, which may reduce latency and improve system performance and reliability at the memory system 110.

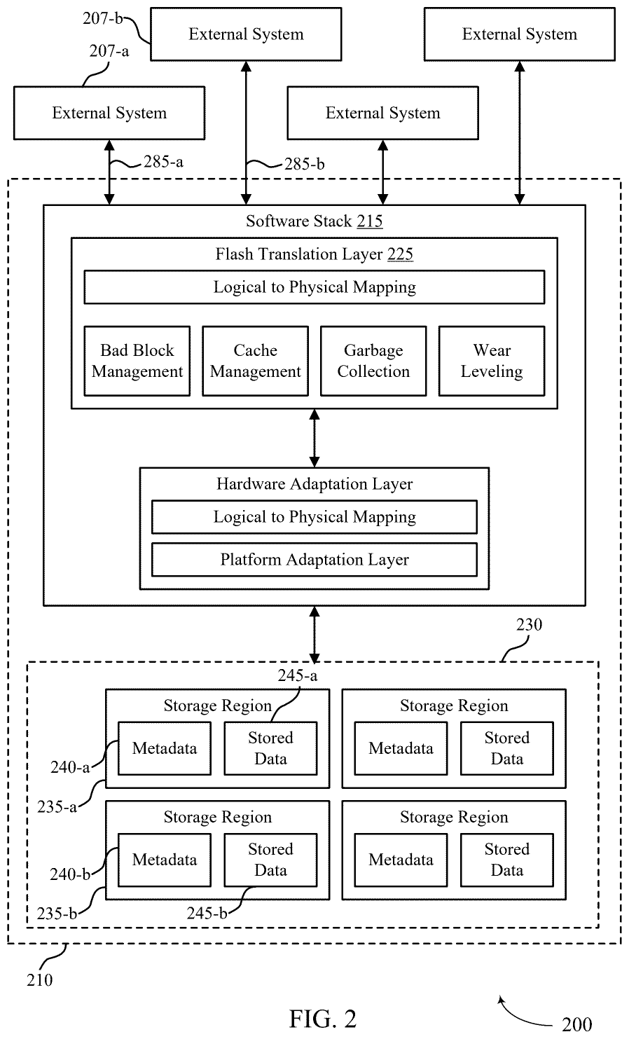

FIG. 2 shows an example of a system 200 that supports independent FTL storage for a memory system in accordance with examples as disclosed herein. In some cases, aspects of the system 200 may implement or be implemented by aspects of FIG. 1. For example, the system 200 may include external systems 207 (e.g., an external system 207-a, an external system 207-b), a memory system 210, FTLs 225, a memory device 230 (e.g., one or more memory devices), and ports 285 (e.g., a port 285-a, a port 285-b), which may be examples of the external systems 107, the memory system 110, the memory devices 130, and the ports 185, respectively, as described herein with respect to FIG. 1. In some aspects, the memory system 210 may receive signaling indicating respective data associated with respective external systems 207, and may execute one or more respective sets of independent FTL functions to manage the respective data.

As described herein, the ports 285 may couple the memory system 210 with the external systems 207. In some cases, each port 285 may couple the memory system 210 with one external system 207, or a plurality of external system 207. For example, the port 285-a may couple the memory system 210 with the external system 207-a (e.g., only the external system 207-a), and the port 285-b may couple the memory system 210 with the external system 207-b and at least one other external system 207. In some cases, each external system 207 may correspond to a lane in a port 285, such that a port 285 may include one or more lanes, where each lane corresponds to an external system 207. In some cases, Table 1 may describe possible configurations of ports 285 and lanes, for example, in a memory system including up to four ports 285. However, the memory system 210 may include more or less ports 285 (e.g., up to 32 ports).

TABLE 1

| Quantity of Ports | Lanes Corresponding to Each Port |
|---|---|
| 1 (Single Port) | Port #0-lanes [0:3] |
| 2 (Dual Port) | Port #0-lanes [0:1] |
| | Port #1-lanes [2:3] |
| 3 (Triple Port) | Port #0-lanes [0:1] |
| | Port #1-lane [2] |
| | Port #2-lane [3] |
| 4 (Quad Port) | Port #0-lanes [0] |
| | Port #1-lane [1] |
| | Port #2-lane [2] |
| | Port #3-lane [3] |

The memory system 210 may also include one or more FTLs 225. An FTL 225 as described herein may represent a set of one or more FTL functions that may be associated with (e.g., executed based on or otherwise in accordance with) respective instructions and parameters, stored as metadata 240. In some cases, an FTL 225 may use the corresponding metadata 240 for mapping logical addresses from a host system to physical addresses in a memory system, which may allow the memory system to determine where data is stored in the memory system. For example, an FTL 225 may be a set of functions executed by the software stack 215. The software stack 215 may execute each respective set of FTL functions on a corresponding stored data 245 based on the instructions or parameters stored in the corresponding metadata 240. Additionally, each FTL 225 may correspond to a respective port 285. In some cases, the FTL functions may include managing an L2P mapping table (e.g., as described herein with respect to FIG. 1), bad block management (e.g., detecting, marking, and replacing blocks that may not be functioning as intended), cache management (e.g., copying data to and removing data from a cache for quicker access to the data), “garbage collection” (e.g., as described herein with respect to FIG. 1), and wear leveling (e.g., distributing data evenly across blocks in the memory device to balance memory cell use and wear).

As an example, executing the FTL functions may include utilizing metadata 240 (e.g., that the memory system 210 stored previously) in the memory system 210. The metadata 240 may guide the FTL functions to determine a physical location within the memory system 210 where incoming data from a host operation may be stored within the memory system 210. In some cases (e.g., in the case of a write operation), the FTL functions may use the metadata 240 to identify an adjacent memory location where the incoming data may be written.

The memory system 210 may support multiple FTLs 225, and the distinction between a first FTL 225 and another FTL 225 may be based part on a separation of instructions or parameters stored in separate metadata 240. For example, a first FTL 225 may correspond to a storage region 235-a which may include metadata 240-a, and a second FTL of the FTLs 225 may correspond to a storage region 235-b which may include metadata 240-b. The metadata 240-a may include instructions or parameters for performing one or more first FTL functions of the first FTL on stored data 245-a stored in the storage region 235-a, and the metadata 240-b may include instructions or parameters for performing one or more second FTL functions of the second FTL on the stored data 245-b stored in the storage region 235-b. In some cases, the stored data 245 may include data from a corresponding external system 207, other data, or both.

In some cases, an FTL failure in an FTL 225 of the memory system 210 may cause one or more symptoms in a corresponding storage region 235. For example, the memory system 210 may set the storage region 235-a to the first operational mode (e.g., write protect, WP) if the memory system 210 detects a failure in a first FTL 225, including if the system 200 is in a remote memory access (RMA) device. In some cases, the memory system 210 may set the storage region 235-a to the first operational mode by modifying the metadata 240-a in the storage region 235-a based on the detected failure, such that the modified metadata 240-a may be associated with reduced write operations for the stored data 245-a (e.g., the namespace). Additionally, the storage region 235-b may remain in a second operational mode (e.g., normal mode, write capable mode, unmodified metadata 240-b) based on a lack of failures in a second FTL 225. Such a symptom of a failed FTL may be relatively common in managed non-volatile memory devices. In some cases, if a memory device 230 is in the first operational mode, the memory device may power-on irregularly because, for example, the memory device 230 may not be capable of supporting booting according to an operating system boot.

In some cases, the FTL failure of the first FTL 225 may be caused by corruption in the metadata 240-a associated with the first FTL 225. For example, the memory system 210 may detect a failure (e.g., corruption) of the first FTL 225 by detecting that an L2P table (e.g., an FTL table) stored in the metadata 240-a (e.g., associated with the first FTL) includes corrupted data. Additionally, or alternatively, the first FTL 225 may detect the error in the metadata 240-a. In some cases, the corrupted data may have various causes, including firmware bugs, temperature or voltage mishandling, a lack of battery power to the system 200, or any combination thereof.

The techniques described herein provide for storage of different sets of metadata 240 in independent storage locations to reduce latency associated with corruption of a given set of metadata 240. Each set of metadata 240 may be associated with (e.g., may indicate) a respective set of instructions, parameters, or both associated with FTL functions, such that the independent sets of metadata 240, when used by the FTL 225, may function as independent FTLs 225. In some aspects, the techniques described herein may provide an alternative to setting the memory device 230 to the first operational mode associated with reduced write capabilities (e.g., a first operational mode, “Write Protect Mode,” “Read Only Mode”) in response to a corrupted FTL. For example, according to the techniques described herein, the memory system 210 may operate (e.g., boot) according to a mode (e.g., boot sequence) alternative to other conventional modes in a case where an FTL associated with one or more ports fails (e.g., when the memory system enters an emergency mode). That is, in the case where the memory system 210 detects a failure associated with an FTL of the FTLs 225, the memory system 210 (e.g., a controller of the memory system 210) may set a storage region 235 corresponding to the FTL to the first operational mode, while one or more other storage regions 235 may continue to operate in a second operational mode (e.g., a normal mode). The independent FTLs 225 may thereby provide for some external systems 207 to continue operations even if one of the FTLs 225 and corresponding metadata 240 is corrupt.

In some cases, the techniques described herein may provide for basic functionality (e.g., reading, writing, managing data according to the FTL functions) within a portion of the storage regions 235 of the memory system 210 in the case of an FTL failure by providing redundancy across the ports 285 of the memory system 210. In some cases, the memory system 210 may provide the basic functionality at least until the memory device may be serviced or repaired in response to the FTL failure. Assuming that the memory system 210 is free of hardware malfunctions (e.g., in the package of the memory system 210, in a controller or microcontroller of the memory system 210), the techniques described herein may also satisfy one or more safety guidelines (e.g., requirements) for automotive vehicles, drones, or other systems associated with high mobility (e.g., rugged systems).

In some examples, each port 285 may be associated with a different FTL 225, and with a different storage region 235 (e.g., FTL management region). For example, each FTL 225 may correspond to at least one storage region 235 and at least one port 285. A first FTL 225 may correspond to the external system 207-a, the port 285-a, and the storage region 235-a. A second FTL 225 may correspond to the external system 207-b, the port 285-b, and the storage region 235-b. The first FTL 225 and the second FTL 225 may be different based on the FTLs 225 being associated with separate sets of metadata 240. For example, the first FTL 225 may be associated with the first set of metadata 240-a, which may include a first set of instructions and parameters, and the second FTL 225 may be associated with the second set of metadata 240-b, which may include a second set of instructions and parameters. Accordingly, the memory system 210 may receive signaling indicating data from the external system 207-a (e.g., or another external system associated with the port 285-a) via the port 285-a, and may (e.g., after storing the data in the storage region 235-a) execute a first set of one or more FTL functions according to the first FTL of the FTLs 225 associated with managing the data, where the first set of one or more FTL functions may be based on the metadata 240-a stored in the storage region 235-a.

Each storage region 235 may be associated with any unit of memory storage. For example, each storage region 235 corresponding to an FTL 225 may include a set of namespaces, a set of logical unit numbers (LUNs), a partition level, or any combination thereof. In some cases, a namespace may be referred to as a memory region, and may include a portion of memory (e.g., non-volatile memory, a first range of logical addresses within a memory device) of a memory system that may be formatted into logical blocks, where each logical block may correspond to one or more physical addresses in the memory device. For example, the stored data 245 may include one or more namespaces (e.g., one or more memory regions), such that the data from an external system 207 may be stored in a corresponding namespace, and the metadata 240 stored in the corresponding storage region of the memory device 230 may include the instructions for executing FTL functions on the data in the namespace. That is, metadata 240 associated with the FTL functions may not reside in the namespace (e.g., in the stored data 245), but may, in some examples, be associated with one or more namespaces. Additionally, or alternatively, a LUN may be a unique identifier that defines a storage partition in a memory device 230, such as a storage region 235 or the stored data 245. In some cases, the FTLs 225 may include one FTL per port 285.

A quantity of independent FTLs 225 that are included in a memory system 210 may vary. In some cases, highly redundant systems may implement the techniques described herein (e.g., including a high quantity of FTLs, such as eight or 16 FTLs). However, implementing a smaller quantity of independent FTLs (e.g., two FTLs) may provide the advantages described herein and may limit system complexity. The techniques described herein may thereby mitigate the negative effects associated with FTL failure. For example, the memory system 210 may detect an FTL failure and may set a corresponding storage region 235 to the first operational mode, while other storage regions 235 may continue operating in the second operational mode.

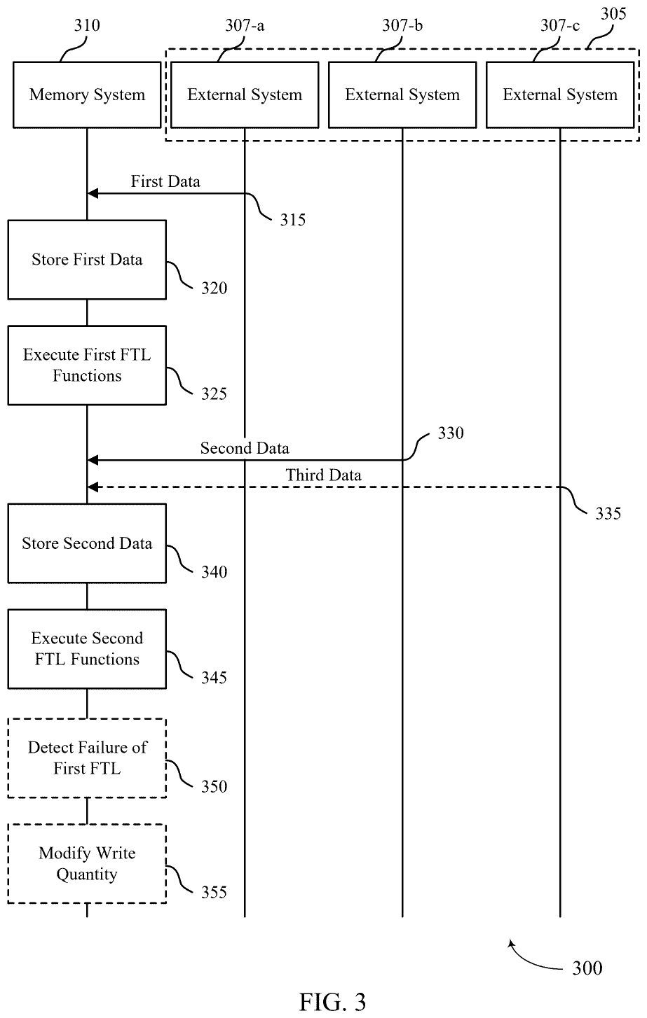

FIG. 3 shows an example of a process flow 300 that supports independent FTL storage for a memory system in accordance with examples as disclosed herein. In some cases, aspects of the process flow 300 may implement or be implemented by aspects of FIGS. 1 and 2. For example, the process flow 300 may include a memory system 310 and external systems 307 (e.g., an external system 307-a, an external system 307-b, an external system 307-c), which may be examples of the memory systems 110 and 210, and the external systems 107 and 207, respectively, as described herein with respect to FIGS. 1 and 2. In some cases, the memory system 310 may receive first signaling indicating first data associated with the external system 307-a, execute one or more first FTL functions on the first data according to a first FTL supported by first metadata, receive second signaling indicating second data associated with the external system 307-b, and execute one or more second FTL functions on the second data according to a second FTL supported by second metadata.

In the following description of process flow 300, the operations may be performed in a different order than the order shown, or other operations may be added or removed from the process flow 300. For example, some operations may also be left out of process flow 300, may be performed in different orders or at different times, or other operations may be added to process flow 300. Although the memory system 310 and a plurality of external systems 305 are shown performing the operations of process flow 300, some aspects of some operations may also be performed by one or more other devices, including memory devices such as the memory device 230, the memory system controller 115, the host system 105, or any combination thereof.

At 315, the memory system 310 may receive first data (e.g., application data, external data) from an external system 307-a for storage in a first namespace (e.g., stored data 245, as described herein with respect to FIG. 2) of the memory system. In some cases, the memory system 310 may support a plurality of external systems 305 that includes the external system 307-a. For example, the memory system 310 may receive the first data via a first port (e.g., such as ports 285 as described herein with respect to FIG. 2), where the memory system 310 may include a plurality of ports that includes the first port, and where the first port may be operable to couple the memory system 310 with the external system 307-a.

Additionally, or alternatively, the first port may be associated with the first namespace (e.g., stored data, storage region 235 as described herein with respect to FIG. 2). In some cases, the first namespace (e.g., the stored data 245, the storage region 235) may include a first range of logical addresses within a memory device (e.g., memory device 230 as described herein with respect to FIG. 2) of the memory system 310. In some cases, the first range of logical addresses may be associated with a first set of memory cells for storing the first data.

At 320, the memory system 310 may store the first metadata and the first data in a first memory device of the memory system 310. For example, the first memory device may be associated with one or more of the external systems 307. In some cases, the memory system may include one or more different memory devices each associated with one or more of the external systems 307.

At 325, the memory system may execute a first set of FTL functions associated with management of the first namespace. In some cases, the memory system 310 may execute the first set of FTL functions based on the first metadata stored in the first storage region of the memory system 310. For example, the first metadata may include first instructions associated with the first set of FTL functions.

In some cases, the memory system 310 may use the FTL functions to manage data storage in the first namespace. For example, executing the first set of FTL functions may include one or more of the following: generating or updating, based on the first metadata, an L2P mapping associated with the first namespace; performing, based on the first metadata, wear levelling which may distribute accesses to the first data across the first namespace; performing, based on the first metadata, one or more garbage collection operations which may delete a portion of the first data from the first namespace, or any combination thereof. In some cases, the FTL functions may include more operations than listed herein.

At 330, the memory system 310 may receive second data from the external system 307-b for storage in the second namespace of the memory system 310, where the plurality of external systems includes the external system 307-b. In some cases, the memory system 310 may receive the second data via a second port (e.g., such as a port 285) of the plurality of ports of the memory system 310. For example, the second port may be operable to couple the memory system 310 with the external system 307-b, and the second port may be associated with the second namespace. Similar to the first namespace, the second namespace may include a second range of logical addresses within a memory device (e.g., the same memory device as the first namespace, a different memory device from the first namespace), where the second range of logical addresses may be associated with a second set of memory cells for storing the second data (e.g., the stored data 245).

At 335, the memory system 310 may receive third data from the external system 307-c. In some cases, the memory system may receive the third data via the second port, where the second data and the third data may be received via separate lanes in the second port. Additionally, or alternatively, the memory system may receive the third data via a third port associated with the memory system 310 and a third namespace within the memory system 310.

At 340, the memory system may store the second data associated with the external system 307-b. For example, the memory system may store the second data in the second namespace, where the second namespace may be in a same memory device in the memory system 310 as the first namespace, or within a second memory device of the memory system (e.g., different from the memory device storing the first namespace). In some cases, the metadata associated with the FTL functions for each namespace may be stored in a same memory device as the respective namespace.

Additionally, or alternatively, the memory device may store the third data associated with the external system 307-c in the second memory device of the memory system 310, where the second memory device may be different from the first memory device. As described herein, the second memory device may also be associated with the external system 307-b. In some cases, the memory system 310 may also store third metadata associated with the third data (e.g., the third metadata being associated with a third set of FTL functions for the third data) in the second memory device.

At 345, the memory system 310 may execute a second set of FTL functions associated with management of the second namespace. For example, the memory system may execute the second set of FTL functions based on the second metadata stored in the second storage region of the memory system 310. In some cases, the second metadata may include second instructions associated with the second set of FTL functions. In some cases, the second set of FTL functions may be similar to the first set of FTL functions (e.g., as described herein at 325), but the second set of FTL functions may apply to the second namespace.

At 350, in some examples, the memory system 310 may detect a failure associated with the first metadata (e.g., associated with the first set of FTL functions. For example, detecting the failure associated with the first metadata may include detecting an error in a portion of the first metadata, where the portion of the first metadata may support the first set of FTL functions. In some cases, the error may be a storage failure (e.g., storing an incorrect bit or set of bits) or an error in communicating the metadata in order to execute the first set of FTL functions.

At 355, in some examples, the memory system may reduce a quantity of write operations in the first storage region based on the detected failure. For example, the modified first metadata may be associated with reduced write operations to the first namespace (e.g., a write protected mode, a read only mode). The memory system 310 may not reduce a quantity of write operations associated with the second storage region (e.g., namespace) associated with the second set of FTL functions based on the failure being associated with the first set of FTL functions. Accordingly, a second namespace associated with the second set of FTL functions may continue operating with normal write operations (e.g., not with the reduced write operations).

Thus, according to the techniques described herein, the memory system 310 may continue executing the second set of FTL functions as normal on the second namespace while the first namespace may be set to a mode associated with reduced write operations based on a failure associated with the first set of FTL function. Such techniques may increase the robustness of the memory system 310 in dealing with failures, and may increase the capabilities of the memory system 310 after detecting a failure.

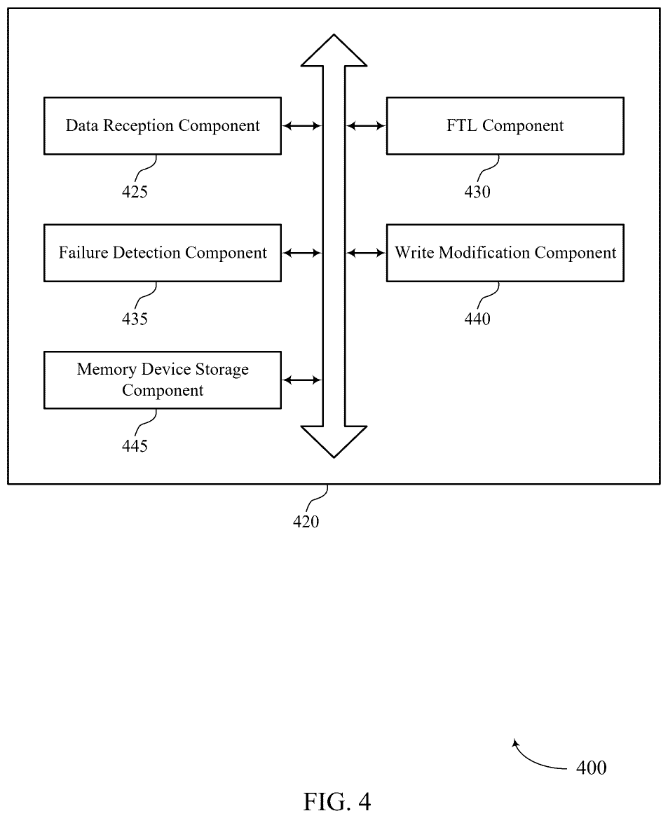

FIG. 4 shows a block diagram 400 of a memory system 420 that supports independent FTL storage for a memory system in accordance with examples as disclosed herein. The memory system 420 may be an example of aspects of a memory system as described with reference to FIGS. 1 through 3. The memory system 420, or various components thereof, may be an example of means for performing various aspects of independent FTL storage for a memory system as described herein. For example, the memory system 420 may include a data reception component 425, an FTL component 430, a failure detection component 435, a write modification component 440, a memory device storage component 445, or any combination thereof. Each of these components, or components of subcomponents thereof (e.g., one or more processors, one or more memories), may communicate, directly or indirectly, with one another (e.g., via one or more buses).

The data reception component 425 may be configured as or otherwise support a means for receiving first data from a first external system for storage in a first memory region of the memory system, where the memory system supports a plurality of external systems that includes the first external system. The FTL component 430 may be configured as or otherwise support a means for executing, based on first metadata stored in a first storage region of the memory system, a first set of FTL functions associated with management of the first memory region, the first metadata including first instructions associated with the first set of FTL functions. In some examples, the data reception component 425 may be configured as or otherwise support a means for receiving second data from a second external system for storage in a second memory region of the memory system, where the plurality of external systems includes the second external system. In some examples, the FTL component 430 may be configured as or otherwise support a means for executing, based on second metadata stored in a second storage region of the memory system, a second set of FTL functions associated with management of the second memory region, the second metadata including second instructions associated with the second set of FTL functions.

In some examples, to support receiving the first data and the second data, the data reception component 425 may be configured as or otherwise support a means for receiving the first data via a first port, where the memory system includes a plurality of ports that includes the first port, and where the first port is operable to couple the memory system with the first external system, the first port associated with the first memory region. In some examples, to support receiving the first data and the second data, the data reception component 425 may be configured as or otherwise support a means for receiving the second data via a second port of the plurality of ports of the memory system, where the second port is operable to couple the memory system with the second external system, the second port associated with the second memory region.

In some examples, the failure detection component 435 may be configured as or otherwise support a means for detecting a failure associated with the first metadata. In some examples, the write modification component 440 may be configured as or otherwise support a means for reducing a quantity of write operations to the first memory region based on the failure, and where a quantity of write operations to the second memory region is not reduced based on the failure being associated with the first metadata.

In some examples, to support detecting the failure associated with the first set of FTL functions, the failure detection component 435 may be configured as or otherwise support a means for detecting an error in a portion of the first metadata, where the portion of the first metadata supports the first set of FTL functions.

In some examples, the memory device storage component 445 may be configured as or otherwise support a means for storing the first metadata and the first data in a first memory device of the memory system, the first memory device associated with the first external system. In some examples, the memory device storage component 445 may be configured as or otherwise support a means for storing third data associated with a third external system in a second memory device of the memory system, the second memory device different from the first memory device and associated with the second external system. In some examples, the memory device storage component 445 may be configured as or otherwise support a means for storing third metadata associated with the third data in the second memory device.

In some examples, to support executing the first set of FTL functions, the FTL component 430 may be configured as or otherwise support a means for generating or updating, based on the first metadata, a logical-to-physical mapping associated with the first memory region.

In some examples, to support executing the first set of FTL functions, the FTL component 430 may be configured as or otherwise support a means for performing, based on the first metadata, wear levelling to distribute accesses to the first data across the first memory region.

In some examples, to support executing the first set of FTL functions, the FTL component 430 may be configured as or otherwise support a means for performing, based on the first metadata, one or more garbage collection operations to delete a portion of the first data from the first memory region.

In some examples, the first memory region includes a first range of logical addresses within a memory device of the memory system, the first range of logical addresses associated with a first set of memory cells for storing the first data. In some examples, the second memory region includes a second range of logical addresses within the memory device, the second range of logical addresses associated with a second set of memory cells for storing the second data.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

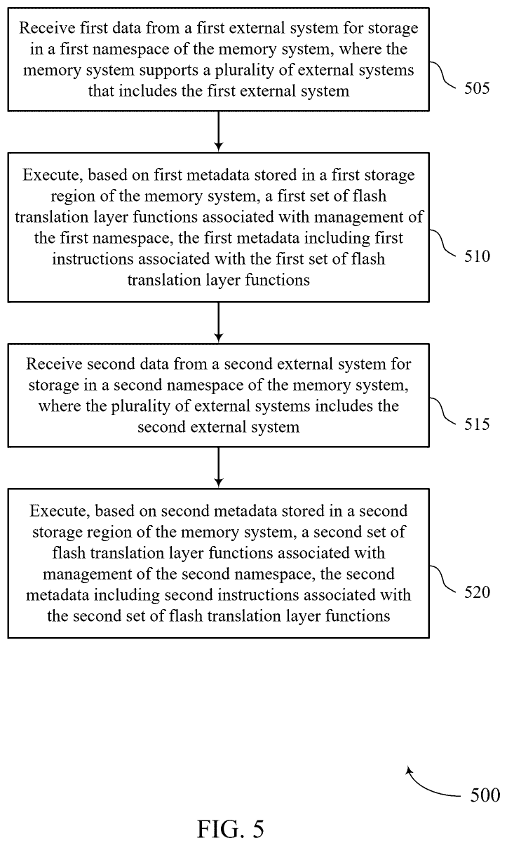

FIG. 5 shows a flowchart illustrating a method 500 that supports independent FTL storage for a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving first data from a first external system for storage in a first memory region of the memory system, where the memory system supports a plurality of external systems that includes the first external system. In some examples, aspects of the operations of 505 may be performed by a data reception component 425 as described with reference to FIG. 4.

At 510, the method may include executing, based on first metadata stored in a first storage region of the memory system, a first set of FTL functions associated with management of the first memory region, the first metadata including first instructions associated with the first set of FTL functions. In some examples, aspects of the operations of 510 may be performed by an FTL component 430 as described with reference to FIG. 4.

At 515, the method may include receiving second data from a second external system for storage in a second memory region of the memory system, where the plurality of external systems includes the second external system. In some examples, aspects of the operations of 515 may be performed by a data reception component 425 as described with reference to FIG. 4.

At 520, the method may include executing, based on second metadata stored in a second storage region of the memory system, a second set of FTL functions associated with management of the second memory region, the second metadata including second instructions associated with the second set of FTL functions. In some examples, aspects of the operations of 520 may be performed by an FTL component 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving first data from a first external system for storage in a first memory region of the memory system, where the memory system supports a plurality of external systems that includes the first external system; executing, based on first metadata stored in a first storage region of the memory system, a first set of FTL functions associated with management of the first memory region, the first metadata including first instructions associated with the first set of FTL functions; receiving second data from a second external system for storage in a second memory region of the memory system, where the plurality of external systems includes the second external system; and executing, based on second metadata stored in a second storage region of the memory system, a second set of FTL functions associated with management of the second memory region, the second metadata including second instructions associated with the second set of FTL functions.

Aspect 2: The method, apparatus, or non-transitory computer-readable medium of aspect 1, where receiving the first data and the second data includes operations, features, circuitry, logic, means, or instructions, or any combination thereof for receiving the first data via a first port, where the memory system includes a plurality of ports that includes the first port, and where the first port is operable to couple the memory system with the first external system, the first port associated with the first memory region and receiving the second data via a second port of the plurality of ports of the memory system, where the second port is operable to couple the memory system with the second external system, the second port associated with the second memory region.

Aspect 3: The method, apparatus, or non-transitory computer-readable medium of any of aspects 1 through 2, further including operations, features, circuitry, logic, means, or instructions, or any combination thereof for detecting a failure associated with the first metadata and reducing a quantity of write operations to the first memory region based on the failure, and where a quantity of write operations to the second memory region is not reduced based on the failure being associated with the first metadata.

Aspect 4: The method, apparatus, or non-transitory computer-readable medium of aspect 3, where detecting the failure associated with the first set of FTL functions includes operations, features, circuitry, logic, means, or instructions, or any combination thereof for detecting an error in a portion of the first metadata, where the portion of the first metadata supports the first set of FTL functions.

Aspect 5: The method, apparatus, or non-transitory computer-readable medium of any of aspects 1 through 4, further including operations, features, circuitry, logic, means, or instructions, or any combination thereof for storing the first metadata and the first data in a first memory device of the memory system, the first memory device associated with the first external system; storing third data associated with a third external system in a second memory device of the memory system, the second memory device different from the first memory device and associated with the second external system; and storing third metadata associated with the third data in the second memory device.

Aspect 6: The method, apparatus, or non-transitory computer-readable medium of any of aspects 1 through 5, where executing the first set of FTL functions includes operations, features, circuitry, logic, means, or instructions, or any combination thereof for generating or updating, based on the first metadata, a logical-to-physical mapping associated with the first memory region.

Aspect 7: The method, apparatus, or non-transitory computer-readable medium of any of aspects 1 through 6, where executing the first set of FTL functions includes operations, features, circuitry, logic, means, or instructions, or any combination thereof for performing, based on the first metadata, wear levelling to distribute accesses to the first data across the first memory region.

Aspect 8: The method, apparatus, or non-transitory computer-readable medium of any of aspects 1 through 7, where executing the first set of FTL functions includes operations, features, circuitry, logic, means, or instructions, or any combination thereof for performing, based on the first metadata, one or more garbage collection operations to delete a portion of the first data from the first memory region.

Aspect 9: The method, apparatus, or non-transitory computer-readable medium of any of aspects 1 through 8, where the first memory region includes a first range of logical addresses within a memory device of the memory system, the first range of logical addresses associated with a first set of memory cells for storing the first data and the second memory region includes a second range of logical addresses within the memory device, the second range of logical addresses associated with a second set of memory cells for storing the second data.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A memory system, including: a memory device including a first memory region associated with a first external system and a second memory region associated with a second external system, the second memory region different from the first memory region, where the memory system supports a plurality of external systems that includes the first external system and the second external system; and one or more controllers coupled with the memory device, the one or more controllers operable to execute one or more FTL functions to manage data for the plurality of external systems supported by the memory system, where: the memory device is operable to store first metadata to support a first set of FTL functions, where the first set of FTL functions is associated with management of first data stored in the first memory region; and the memory device is operable to store second metadata to support a second set of FTL functions, where the second set of FTL functions is associated with management of second data stored in the second memory region.

Aspect 11: The memory system of aspect 10, further including: a first port operable to couple the memory system with the first external system, where the first memory region and the first set of FTL functions are associated with the first port; and a second port operable to couple the memory system with the second external system, where the second memory region and the second set of FTL functions are associated with the second port.

Aspect 12: The memory system of any of aspects 10 through 11, where the one or more controllers are operable to: detect a failure associated with the first metadata; and reduce a quantity of write operations to the first memory region based on the failure, and where a quantity of write operations to the second memory region is not reduced based on the failure being associated with the first metadata.

Aspect 13: The memory system of aspect 12, where, to detect the failure associated with the first set of FTL functions, the one or more controllers are operable to: detect an error in a portion of the first metadata, where the portion of the first metadata supports the first set of FTL functions.

Aspect 14: The memory system of any of aspects 10 through 13, where: the first memory region includes a first range of logical addresses within the memory device, the first range of logical addresses associated with a first set of memory cells for storing the first data; and the second memory region includes a second range of logical addresses within the memory device, the second range of logical addresses associated with a second set of memory cells for storing the second data.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method at a memory system, comprising:
receiving first data from a first external system for storage in a first memory region of the memory system, wherein the memory system supports a plurality of external systems that includes the first external system;
executing, based on first metadata stored in a first storage region of the memory system, a first set of flash translation layer functions associated with management of the first memory region, the first metadata comprising first instructions associated with the first set of flash translation layer functions;
receiving second data from a second external system for storage in a second memory region of the memory system, wherein the plurality of external systems includes the second external system; and
executing, based on second metadata stored in a second storage region of the memory system, a second set of flash translation layer functions associated with management of the second memory region, the second metadata comprising second instructions associated with the second set of flash translation layer functions.

2. The method of claim 1, wherein receiving the first data and the second data comprises:
receiving the first data via a first port, wherein the memory system comprises a plurality of ports that includes the first port, and wherein the first port is operable to couple the memory system with the first external system, the first port associated with the first memory region; and
receiving the second data via a second port of the plurality of ports of the memory system, wherein the second port is operable to couple the memory system with the second external system, the second port associated with the second memory region.

3. The method of claim 1, further comprising:
detecting a failure associated with the first metadata; and
reducing a quantity of write operations to the first memory region based on the failure, and wherein a quantity of write operations to the second memory region is not reduced based on the failure being associated with the first metadata.

4. The method of claim 3, wherein detecting the failure associated with the first set of flash translation layer functions comprises:
detecting an error in a portion of the first metadata, wherein the portion of the first metadata supports the first set of flash translation layer functions.

5. The method of claim 1, further comprising:
storing the first metadata and the first data in a first memory device of the memory system, the first memory device associated with the first external system;
storing third data associated with a third external system in a second memory device of the memory system, the second memory device different from the first memory device and associated with the second external system; and
storing third metadata associated with the third data in the second memory device.

6. The method of claim 1, wherein executing the first set of flash translation layer functions comprises:
generating or updating, based on the first metadata, a logical-to-physical mapping associated with the first memory region.

7. The method of claim 1, wherein executing the first set of flash translation layer functions comprises:
performing, based on the first metadata, wear levelling to distribute accesses to the first data across the first memory region.

8. The method of claim 1, wherein executing the first set of flash translation layer functions comprises:
performing, based on the first metadata, one or more garbage collection operations to delete a portion of the first data from the first memory region.

9. The method of claim 1, wherein:
the first memory region comprises a first range of logical addresses within a memory device of the memory system, the first range of logical addresses associated with a first set of memory cells for storing the first data; and
the second memory region comprises a second range of logical addresses within the memory device, the second range of logical addresses associated with a second set of memory cells for storing the second data.

10. A memory system, comprising:
a memory device comprising a first memory region associated with a first external system and a second memory region associated with a second external system, the second memory region different from the first memory region, wherein the memory system supports a plurality of external systems that includes the first external system and the second external system; and
one or more controllers coupled with the memory device, the one or more controllers operable to execute one or more flash translation layer functions to manage data for the plurality of external systems supported by the memory system, wherein:
the memory device is operable to store first metadata to support a first set of flash translation layer functions, wherein the first set of flash translation layer functions is associated with management of first data stored in the first memory region; and
the memory device is operable to store second metadata to support a second set of flash translation layer functions, wherein the second set of flash translation layer functions is associated with management of second data stored in the second memory region.

11. The memory system of claim 10, further comprising:
a first port operable to couple the memory system with the first external system, wherein the first memory region and the first set of flash translation layer functions are associated with the first port; and
a second port operable to couple the memory system with the second external system, wherein the second memory region and the second set of flash translation layer functions are associated with the second port.

12. The memory system of claim 10, wherein the one or more controllers are operable to:
detect a failure associated with the first metadata; and
reduce a quantity of write operations to the first memory region based on the failure, and wherein a quantity of write operations to the second memory region is not reduced based on the failure being associated with the first metadata.

13. The memory system of claim 12, wherein, to detect the failure associated with the first set of flash translation layer functions, the one or more controllers are operable to:
detect an error in a portion of the first metadata, wherein the portion of the first metadata supports the first set of flash translation layer functions.

14. The memory system of claim 10, wherein:
the first memory region comprises a first range of logical addresses within the memory device, the first range of logical addresses associated with a first set of memory cells for storing the first data; and
the second memory region comprises a second range of logical addresses within the memory device, the second range of logical addresses associated with a second set of memory cells for storing the second data.

15. A memory system, comprising:
one or more memories storing processor-executable code; and
one or more processors coupled with the one or more memories and individually or collectively operable to execute the code to cause the memory system to:
receive first data from a first external system for storage in a first memory region of the memory system, wherein the memory system supports a plurality of external systems that includes the first external system;
executing, based on first metadata stored in a first storage region of the memory system, a first set of flash translation layer functions associated with management of the first memory region, the first metadata comprising first instructions associated with the first set of flash translation layer functions;
receive second data from a second external system for storage in a second memory region of the memory system, wherein the plurality of external systems includes the second external system; and
executing, based on second metadata stored in a second storage region of the memory system, a second set of flash translation layer functions associated with management of the second memory region, the second metadata comprising second instructions associated with the second set of flash translation layer functions.

16. The memory system of claim 15, wherein, to receive the first data and the second data, the one or more processors are individually or collectively operable to execute the code to cause the memory system to:
receive the first data via a first port, wherein the memory system comprises a plurality of ports that includes the first port, and wherein the first port is operable to couple the memory system with the first external system, the first port associated with the first memory region; and
receive the second data via a second port of the plurality of ports of the memory system, wherein the second port is operable to couple the memory system with the second external system, the second port associated with the second memory region.

17. The memory system of claim 15, wherein the one or more processors are individually or collectively further operable to execute the code to cause the memory system to:
detect a failure associated with the first metadata; and
reduce a quantity of write operations to the first memory region based on the failure, and wherein a quantity of write operations to the second memory region is not reduced based on the failure being associated with the first metadata.

18. The memory system of claim 17, wherein, to detect the failure associated with the first set of flash translation layer functions, the one or more processors are individually or collectively operable to execute the code to cause the memory system to:
detect an error in a portion of the first metadata, wherein the portion of the first metadata supports the first set of flash translation layer functions.

19. The memory system of claim 15, wherein the one or more processors are individually or collectively further operable to execute the code to cause the memory system to:
store the first metadata and the first data in a first memory device of the memory system, the first memory device associated with the first external system;
store third data associated with a third external system in a second memory device of the memory system, the second memory device different from the first memory device and associated with the second external system; and
store third metadata associated with the third data in the second memory device.

20. The memory system of claim 15, wherein, to execute the first set of flash translation layer functions, the one or more processors are individually or collectively operable to execute the code to cause the memory system to:
generate or updating, based on the first metadata, a logical-to-physical mapping associated with the first memory region.

21. The memory system of claim 15, wherein, to execute the first set of flash translation layer functions, the one or more processors are individually or collectively operable to execute the code to cause the memory system to:
perform, based on the first metadata, wear levelling to distribute accesses to the first data across the first memory region.

22. The memory system of claim 15, wherein, to execute the first set of flash translation layer functions, the one or more processors are individually or collectively operable to execute the code to cause the memory system to:
perform, based on the first metadata, one or more garbage collection operations to delete a portion of the first data from the first memory region.

23. The memory system of claim 15, wherein:
the first memory region comprises a first range of logical addresses within a memory device of the memory system, the first range of logical addresses associated with a first set of memory cells for storing the first data; and
the second memory region comprises a second range of logical addresses within the memory device, the second range of logical addresses associated with a second set of memory cells for storing the second data.
